(19) United States
(12) Patent Application Publication
(10) Pub. No.: US 2019/0334502 A1
(43) Pub. Date: Oct. 31, 2019

(54) SURFACE ACOUSTIC WAVE (SAW) DEVICE STRUCTURE WITH FAST TRAP REGION

(71) Applicant: SNAPTRACK, INC., San Diego, CA (US)

(72) Inventor: Quirin Peter UNTERREITHMEIER, Munich (DE)

(21) Appl. No.: 15/966,212

(22) Filed: Apr. 30, 2018

(51) Int. Cl. H03H 9/145; H03H 9/05

(52) U.S. Cl. CPC H03H 9/14552; H03H 9/058

(57) ABSTRACT

Certain aspects of the present disclosure provide a surface acoustic wave (SAW) device having an interdigitated transducer (IDT) with at least one fast trap region. One example SAW device generally includes a substrate and an IDT disposed above the substrate and comprising a plurality of electrodes. In certain aspects, a first electrode of the plurality of electrodes may include a first region, a second region, and a third region, where the second region is disposed between the first and third regions. In some cases, a width of the first electrode in the first region is greater than a width of the first electrode in the second region and less than a width of the first electrode in the third region.

### TECHNICAL FIELD

Certain aspects of the present disclosure generally relate to surface acoustic wave (SAW) devices and, more particularly, to an interdigitated transducer (IDT) of a SAW device.

### BACKGROUND

A surface acoustic wave (SAW) is an acoustic wave traveling along the surface of a piezoelectric substrate. SAW devices use these waves to achieve certain functions. For example, SAW devices may be implemented as filters, oscillators, or transformers, using transduction of acoustic waves, by converting electric energy to mechanical energy, and vice versa, using one or more interdigitated transducers (IDTs) disposed above a piezoelectric substrate.

### SUMMARY

Certain aspects of the present disclosure generally relate to surface acoustic wave (SAW) devices with one or more fast trap regions in the interdigitated transducer (IDT).

Certain aspects of the present disclosure provide a SAW device. The SAW device generally includes a substrate and an IDT disposed above the substrate and comprising a plurality of electrodes. In certain aspects, a first electrode of the plurality of electrodes comprises a first region, a second region, and a third region; the second region is disposed between the first and third regions; and a width of the first electrode in the first region is greater than a width of the first electrode in the second region and less than a width of the first electrode in the third region.

Certain aspects of the present disclosure provide a SAW device. The SAW device may include a substrate and an IDT disposed above the substrate and comprising a first set of electrodes and a second set of electrodes. In certain aspects, at least a portion of each of the first set of electrodes is disposed between an adjacent pair of electrodes in the second set of electrodes; each electrode of the first set of electrodes and the second set of electrodes comprises a first region, a second region, and a third region; the second region is disposed between the first region and the third region; and a width of the first region is greater than a width of the second region and less than a width of the third region.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIGS. 4A and 4B illustrate example surface acoustic wave (SAW) resonators, in accordance with certain aspects of the present disclosure.

FIGS. 5A and 5B illustrate example electrodes of an interdigitated transducer (IDT), in accordance with certain aspects of the present disclosure.

FIG. 6 is a graph illustrating velocity and amplitude of a SAW resonator, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

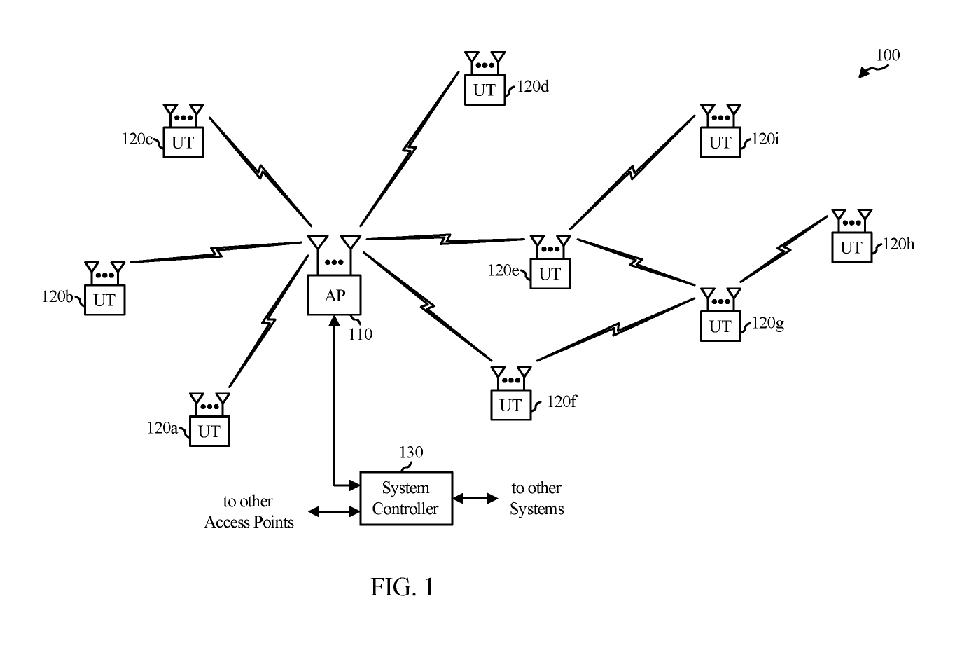

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In certain aspects of the present disclosure, the access point 110 and/or user terminal 120 may include at least one surface acoustic wave (SAW) device, as described in more detail herein.

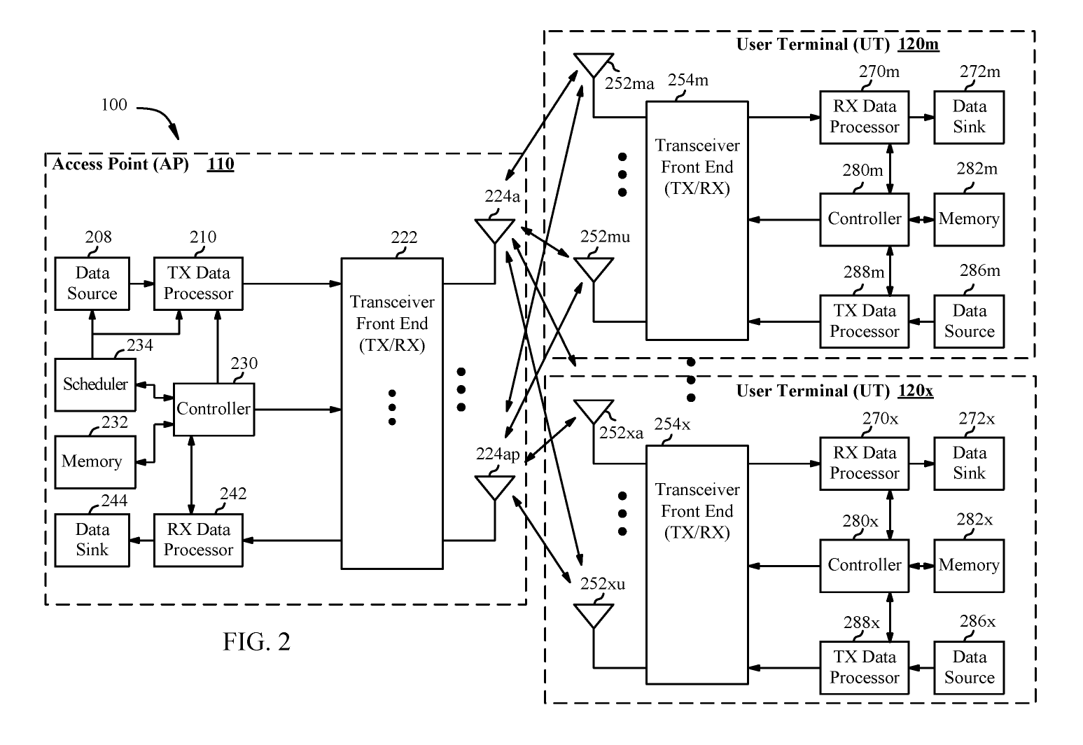

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing. The transceiver front end (TX/RX) 222 of access point 110 and/or transceiver front end 254 of user terminal 120 may include one or more SAW devices as described in more detail herein.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

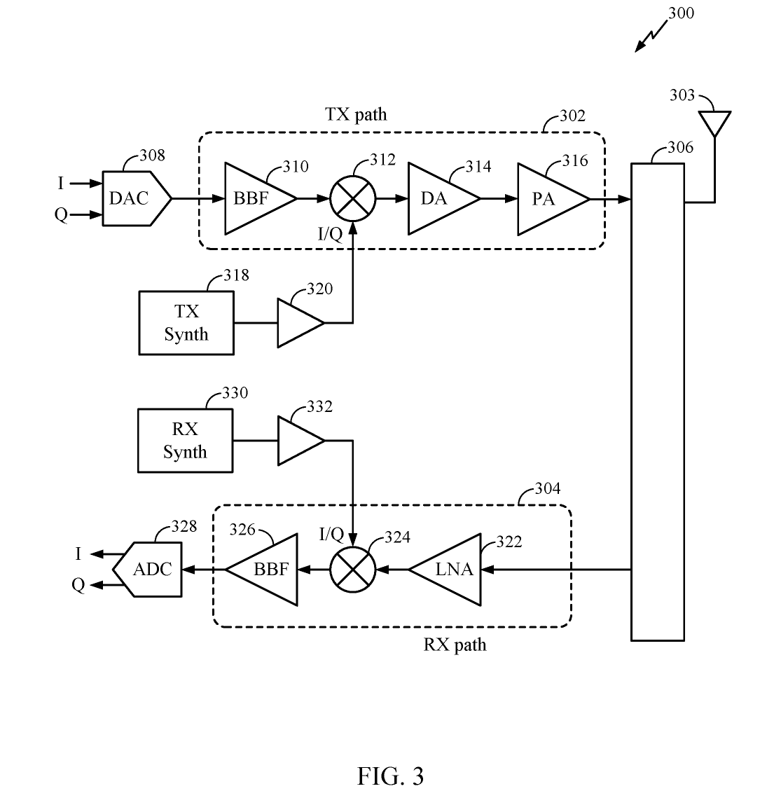

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning the LO to different frequencies typically entails using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324.

FIGS. 1-3 provide a wireless communication system as an example application in which certain aspects of the present disclosure may be implemented to facilitate understanding. However, certain aspects provided herein can be applied to any of various other suitable systems.

### Example Surface Acoustic Wave (SAW) Device

A surface acoustic wave (SAW) is an acoustic wave traveling along the surface of a piezoelectric substrate. SAW devices may be implemented as filters, oscillators, or transformers, using transduction of acoustic waves, by converting electric energy to mechanical energy, and vice versa, using one or more interdigitated transducers (IDTs) disposed above a piezoelectric substrate. IDTs may have two interdigitated comb-shaped arrays of electrodes used to convert acoustic waves to electrical signals, and vice versa, by exploiting the piezoelectric effect of the piezoelectric substrate, as described in more detail herein.

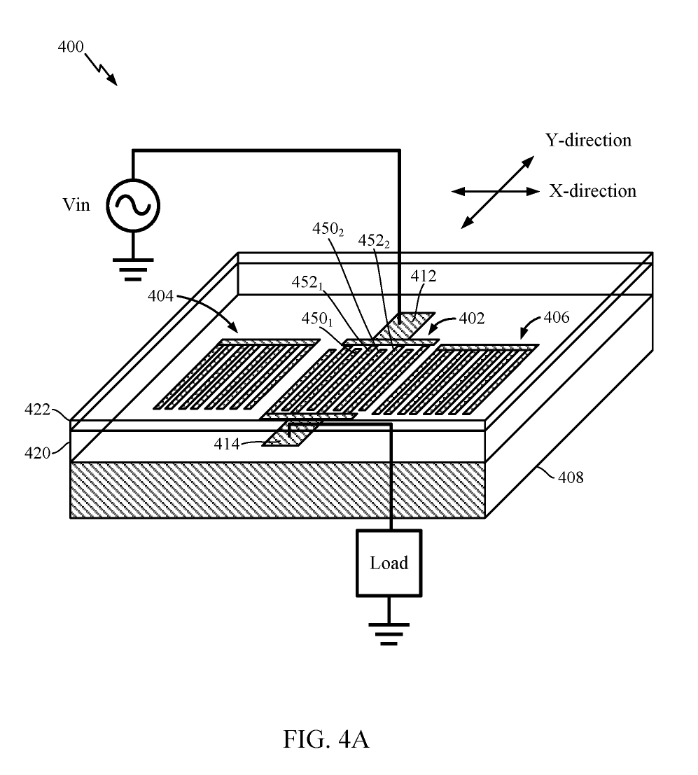

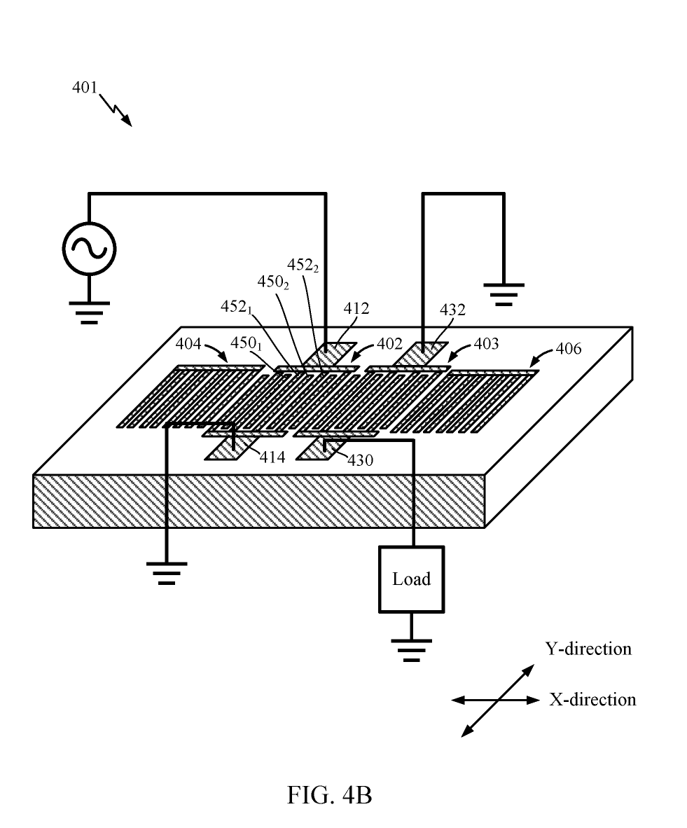

FIGS. 4A and 4B illustrate example SAW resonators 400 and 401, respectively, in accordance with certain aspects of the present disclosure. As illustrated in FIG. 4A, the SAW resonator 400 includes an IDT 402 disposed above a piezoelectric substrate 408 and between two reflectors 404 and 406. The IDT 402 includes two comb-shaped electrode sets (e.g., including electrodes 450₁, 450₂, 452₁, and 452₂) that are interdigitated, as illustrated. When an electrical signal Vin is applied at a terminal 412, the piezoelectric substrate 408 resonates causing SAWs propagating towards the reflectors 404 and 406. The SAWs reflect off the reflectors 404 and 406, causing a resonance at a particular frequency and at the output terminal 414. In certain aspects, the IDT 402 and reflectors 404 and 406 may be disposed in dielectric material 420 (e.g., silicon dioxide), disposed below a layer of silicon nitride (Si₃N₄) 422, as illustrated.

While the example SAW resonator 400 is implemented using a single IDT 402 to facilitate understanding, any number of IDTs may be used. For example, as illustrated in FIG. 4B, a second IDT 403 may be disposed between the reflectors 404 and 406. In this case, the input voltage Vin may be applied between terminals 412 and 414 to generate a resonance at the output nodes 430 and 432, as illustrated.

SAW resonator structures employ a specific mechanical resonance, and in order to function properly, it may be desirable to suppress other mechanical resonances of the SAW resonator. For example, unwanted resonances called transversal modes may be characterized by their acoustic energy distribution in the active area of the SAW resonator. Transversal modes are vibrations propagating across the SAW resonator in the transverse direction (e.g., direction perpendicular to the direction of energy transfer). Certain aspects of the present disclosure provide a SAW resonator configured to reduce the coupling to these transversal modes by suitably shaping the velocity profile (and therefore the amplitude profile) as described in detail below.

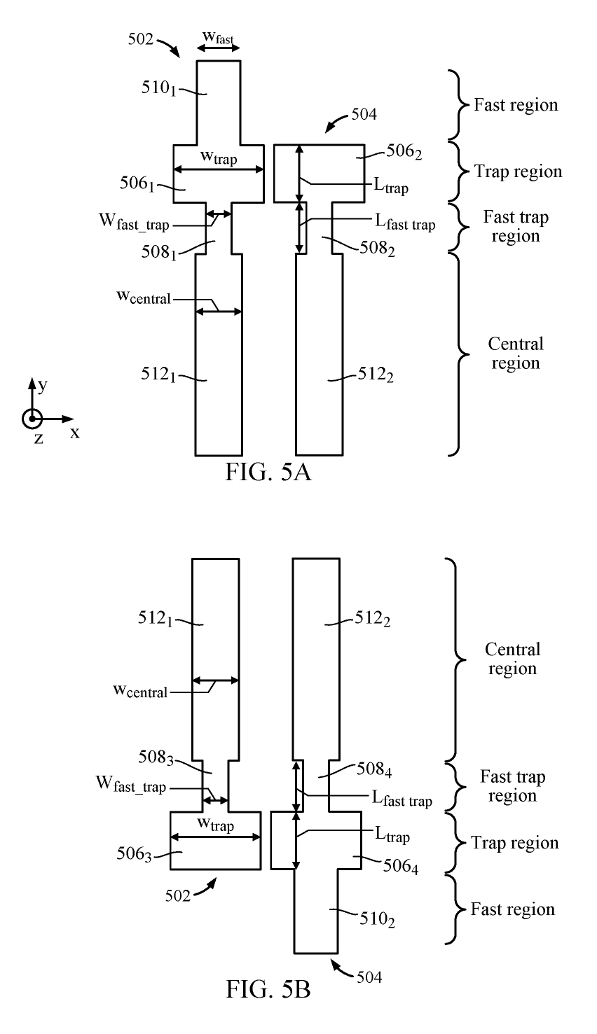

FIGS. 5A and 5B illustrate top and bottom end regions of two electrodes of an IDT (e.g., IDT 402 of FIG. 4A), in accordance with certain aspects of the present disclosure. As used herein, the term “top end region” generally refers to the upper end region of the IDT if the IDT is rotated such that the electrodes are oriented vertically and the IDT is viewed from the side (i.e., perpendicular to the plane of the IDT). Likewise, the term “bottom end region” generally refers to the lower end region of the IDT if the IDT has this same rotation and is viewed from this same perspective. For example, electrode 502 may correspond to electrode 452₁ of the IDT 402 described with respect to FIGS. 4A and 4B, and electrode 504 may correspond to electrode 450₂ of the IDT 402. For instance, FIG. 5A illustrates the top end regions (e.g., regions closest to terminal 412) of the electrodes 452₁ and 450₂, and FIG. 5B illustrates the bottom end regions (e.g., regions closest to terminal 414) of the electrodes 452₁ and 450₂.

As illustrated in FIG. 5A, each of the electrodes 502 and 504 includes a respective trap region 506₁ and 506₂ at the top end (collectively, “trap regions 506”). The central regions 512₁ and 512₂ (collectively, “central regions 512”) extend from the top end of the respective electrodes 502 and 504, as illustrated in FIG. 5A, to the bottom end of the respective electrodes, as illustrated in FIG. 5B. At the bottom end, each of the electrodes 502 and 504 includes another respective trap region 506₃ and 506₄. In certain aspects, the height (visualized as the depth into the page) of the electrodes 502 and 504 may be substantially the same for the various regions at the top end and the bottom end of the electrodes.

Each of the electrodes 502 and 504 is part of an electrode set, as described with respect to FIGS. 4A and 4B. Thus, each of the electrodes 502 and 504 includes a respective fast region 510₁ and 510₂ (collectively, “fast regions 510”) for coupling the electrodes 502 and 504 to other electrodes of their respective electrode sets.

The trap regions 506 at the ends of the active region (e.g., overlapping region of electrodes 502 and 504) reduce the acoustic velocity and provide an acoustic energy distribution in the Y-direction of the IDT referred to as piston mode. The Y-direction is the propagation direction of the transverse mode vibrations along the long axis of the electrodes 502 and 504. The piston mode is characterized by a flat amplitude of the acoustic wave travelling across the center region, with an exponentially decreasing amplitude at the edges (trap region) of the IDT electrodes.

As illustrated, each of the trap regions of the electrodes 502 and 504 has a width Wₜᵣₐₚ in the X-direction that is greater than the widths W_{central} and W_{fast} of the electrodes 502 and 504 in the central region, and the fast region, respectively, where the X-direction is perpendicular to the Y-direction. For certain aspects, the width of the electrode 502 in the trap regions 506₁ and 506₃ may be substantially the same as the width of the electrode 504 in the trap regions 506₂ and 506₄, while in other aspects, these widths may be different.

The greater width of the trap region, and resultant increase in mass, results in a reduction of the acoustic wave propagation in the Y-direction. The velocity of the acoustic wave is dependent on the interplay between the stiffness of the electrodes and their inertia. Thus, by adding mass to the electrode in the trap region, the velocity of the acoustic wave is slowed. Therefore, due to the wider width of the trap region, and resultant increased mass, the velocity of the acoustic wave moving across the trap region is reduced.

Certain aspects of the present disclosure provide techniques to further reduce the velocity of the acoustic wave by adding a fast trap region. For example, as illustrated in FIG. 5A, each of the electrodes 502 and 504 includes a respective fast trap region 508₁, 508₂ at the top end and another respective fast trap region 508₃, 508₄ at the bottom end (collectively, “fast trap regions 508”). A width W_{fast_trap} of the electrodes 502 and 504 in the fast trap regions 508 may be less than any one of the widths Wₜᵣₐₚ, W_{central}, and W_{fast}. In certain aspects, the widths of the electrodes 502 and 504 in the fast trap regions 508 may be less than the widths of the electrodes 502 and 504 in the trap regions 506 by about a factor of three. For certain aspects, the width of the electrode 502 in the fast trap regions 508₁, 508₃ may be substantially the same as the width of the electrode 504 in the fast trap regions 508₂, 508₄, while in other aspects, these widths may be different. In some cases, the length Lₜᵣₐₚ of the electrodes 502 and 504 in the trap regions 506 may be less than the length L_{fast trap} of the electrodes 502 and 504 in the fast trap regions 508.

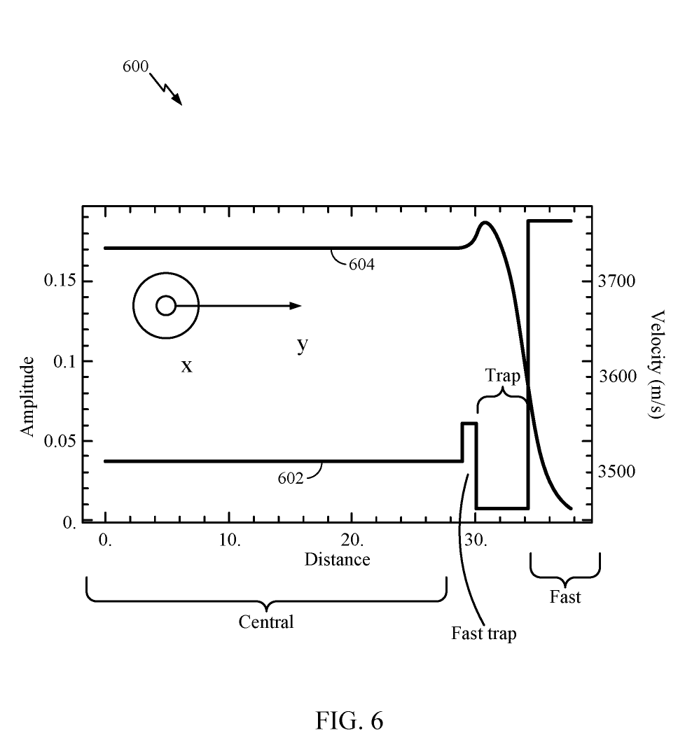

FIG. 6 is a graph 600 illustrating the velocity of acoustic wave propagation across an IDT having electrodes implemented with a fast trap region, in accordance with certain aspects of the present disclosure. The left Y-axis of the graph 600 represents the relative amplitude of the acoustic wave as a ratio of the total amplitude integrated across the X-axis (distance), and the right Y-axis of the graph represents the velocity of the acoustic wave in meters per second (m/s). The curve 602 represents the velocity of the acoustic wave in the Y-direction (along the long axis of an electrode). As illustrated, the velocity of the acoustic wave increases in the fast trap region relative to the center region, but decreases in the trap region. Consequently, the amplitude of the acoustic wave in the Y-direction increases due to the fast trap region, with a decrease of the amplitude due to the trap region, as illustrated by curve 604.

While the fast trap region results in an increase in the velocity of the acoustic wave across the fast trap region, the fast trap region also results in the acoustic wave velocity decreasing more aggressively across the trap region. Thus, the inclusion of the fast trap region effectively decreases the acoustic wave velocity traveling across the trap region by a greater amount as compared to an IDT implemented without the fast trap region. Therefore, the combination of the fast trap region and trap region reduces the coupling to the transversal mode vibrations.

As described with respect to FIGS. 5A and 5B, certain aspects of the present disclosure provide a SAW device (e.g., SAW resonator 400) having a substrate (e.g., the piezoelectric substrate 408), and an IDT (e.g., IDT 402) disposed above the substrate. In certain aspects, the IDT includes a plurality of electrodes. A first electrode (e.g., electrode 502 which may correspond to electrode 452₁) of the plurality of electrodes comprises a first region (e.g., the central region 512₁), a second region (e.g., the fast trap region 508₃), and a third region (e.g., the trap region 506₃). For example, the second region may be disposed between the first and third regions, and a width of the first electrode in the first region may be greater than a width of the first electrode in the second region and less than a width of the first electrode in the third region.

In certain aspects, a second electrode (e.g., electrode 504 which may correspond to electrode 450₂) of the plurality of electrodes may include a fourth region (e.g., central region 512₂), a fifth region (e.g., fast trap region 508₄), and a sixth region (e.g., trap region 506₄). In this case, the fifth region may be disposed between the fourth and sixth regions, and a width of the second electrode in the fourth region is greater than a width of the second electrode in the fifth region and less than a width of the second electrode in the sixth region.

In some cases, the SAW device may also include a third electrode (e.g., the electrode 450₁) of the plurality of electrodes having a seventh region, an eighth region, and a ninth region (e.g., the seventh, eighth, and ninth regions may be analogous to the central region 512₂, the fast trap region 508₄, and the trap region 506₄, respectively, but for another electrode (e.g., electrode 450₁) disposed adjacent to the electrode 502). In this case, the third electrode and the second electrode are coupled to a first terminal (e.g., terminal 414) of the IDT and the first electrode may be coupled to a second terminal (e.g., terminal 412) of the IDT. In certain aspects, at least a portion of the first electrode (e.g., electrode 502) may be disposed between the second electrode and the third electrode, the eighth region may be disposed between the seventh region and the ninth region, and a width of the third electrode in the seventh region may be greater than a width of the third electrode in the eighth region and less than a width of the second electrode in the ninth region.

In certain aspects, the first region (e.g., the central region 512₁) of the first electrode is disposed adjacent to the fourth region (e.g., central region 512₂) of the second electrode, the second region (e.g., the fast trap region 508₃) of the first electrode is disposed adjacent to the fifth region (e.g., the fast trap region 508₄) of the second electrode, and the third region (e.g., the trap region 506₃) of the first electrode is disposed adjacent to the sixth region (e.g., the trap region 506₄) of the second electrode.

In certain aspects, the first and second electrodes (e.g., electrodes 502 and 504) are configured such that a velocity of an acoustic wave configured to flow between the second region and the fifth region is greater than a velocity of another acoustic wave configured to flow between the third region and the sixth region.

In certain aspects, the first region (e.g., the central region 512₁) of the first electrode and the fourth region (e.g., the central region 512₂) of the second electrode have the same length, width, and height, the second region (e.g., the fast trap region 508₃) of the first electrode and the fifth region (e.g., fast trap region 508₄) of the second electrode have the same length, width, and height, and the third region (e.g., trap region 506₃) of the first electrode and the sixth region (e.g., trap region 506₄) of the second electrode have the same length, width, and height.

In certain aspects, the second electrode may include a seventh region (e.g., the fast region 510₂) disposed adjacent to the sixth region (e.g., trap region 506₄) of the second electrode. In this case, a width of the second electrode in the seventh region (e.g., the fast region 510₂) is greater than the width of the second electrode in the fifth region (e.g., fast trap region 508₄) and less than the width of the second electrode in the sixth region (e.g., trap region 506₄). In certain aspects, the width of the second electrode in the seventh region (e.g., the fast region 510₂) is the same as the width of the second electrode in the fourth region (e.g., the central region 512₂).

In certain aspects, the first electrode (e.g., electrode 502) comprises a seventh region (e.g., the fast trap region 508₁) and an eighth region (e.g., the trap region 506₁). In this case, the seventh region (e.g., the fast trap region 508₁) is disposed between the first region (e.g., the central region 512₁) and the eighth region (e.g., the trap region 506₁). For example, the width of the first electrode in the first region (e.g., the central region 512₁) is greater than a width of the first electrode in the seventh region (e.g., the fast trap region 508₁) and less than a width of the first electrode in the eighth region (e.g., the trap region 506₁).

In certain aspects, the second electrode (e.g., electrode 504) includes a ninth region (e.g., the fast trap region 508₂) and a tenth region (e.g., trap region 506₂). For example, the ninth region (e.g., the fast trap region 508₂) may be disposed between the fourth region (e.g., the central region 512₂) and the tenth region (e.g., the trap region 506₂). The width of the second electrode in the fourth region (e.g., the central region 512₂) may be greater than a width of the second electrode in the ninth region (e.g., the fast trap region 508₂) and less than a width of the second electrode in the tenth region (e.g., the trap region 506₂). In certain aspects, the seventh region (e.g., the fast trap region 508₁) of the first electrode is disposed adjacent to the ninth region (e.g., the fast trap region 508₂) of the second electrode, and the eighth region (e.g., trap region 506₁) of the first electrode is disposed adjacent to the tenth region (e.g., trap region 506₂) of the second electrode.

In certain aspects, a length of the second region (e.g., fast trap region 508₃) is less than a length of the third region (e.g., the trap region 506₃) in the first electrode. In certain aspects, the SAW device also includes a dielectric region (e.g., dielectric material 420) disposed between the plurality of electrodes.

In certain aspects, the first electrode (e.g., electrode 502) may also include a fourth region (e.g., the fast trap region 508₁) and a fifth region (e.g., the trap region 506₁), the fourth region being disposed between the first region and the fifth region. The width of the first electrode in the first region may be greater than a width of the first electrode in the fourth region and less than a width of the first electrode in the fifth region. In some cases, the second and fourth regions (e.g., the fast trap regions 508₃ and 508₁) of the first electrode may have the same width, and the third and fifth regions (e.g., the trap regions 506₃ and the 506₁) of the first electrode may have the same width. In certain aspects, the first, second, third, fourth, and fifth regions of the first electrode are disposed linearly along the same axis, are disposed in the same layer of the SAW device, and have the same height.

Certain aspects of the present disclosure provide a SAW device (e.g., the SAW resonator 400). The SAW device generally includes a substrate (e.g., a piezoelectric substrate) and an IDT (e.g., the IDT 402) disposed above the substrate and comprising a first set of electrodes (e.g., including at least electrodes 450₁ and 450₂) and a second set of electrodes, (e.g., including at least electrodes 452₁ and 452₂). In this case, at least a portion of each of the first set of electrodes is disposed between an adjacent pair of electrodes in the second set of electrodes.

In certain aspects, each electrode of the first set of electrodes and the second set of electrodes comprises a first region (e.g., central regions 512₁ and 512₂), a second region (e.g., fast trap regions 508₁ and 508₂), and a third region (e.g., the trap region 506₁ and 506₂). For example, the second region (e.g., fast trap regions 508₁) may be disposed between the first region (e.g., central region 512₁) and the third region (e.g., trap region 506₁), and a width of the first region (e.g., central region 512₁) may be greater than a width of the second region (e.g., fast trap regions 508₁) and less than a width of the third region (e.g., trap region 506₁). In certain aspects, the first, second, and third regions of one of the first set of electrodes are disposed adjacent to the first, second, and third regions of one of the second set of electrodes, respectively. In certain aspects, each of the first set of electrodes may also include a fourth region (e.g., fast region 510₁), the fourth region extending beyond a length of each of the second set of electrodes. A width of the fourth region may be greater than the width of the second region (e.g., the fast trap region 508₁) and less than the width of the third region (e.g., trap region 506₁).

In certain aspects, the first regions (e.g., the central regions 512₁ and 512₂) of the first set of electrodes and the second set of electrodes have the same length, width, and height, the second regions (e.g., the fast trap regions 508₁ and 508₂) of the first set of electrodes and the second set of electrodes have the same length, width, and height, and the third regions (e.g., trap region 506₁ and 506₂) of the first set of electrodes and the second set of electrodes have the same length, width, and height.

In certain aspects, each electrode of the first set of electrodes and the second set of electrodes comprises a fourth region (e.g., the fast trap regions 508₃ and 508₄) and a fifth region (e.g., the trap regions 506₃ and 506₄). In this case, the fourth region (e.g., the fast trap region 508₃) of the first set of electrodes is disposed between the first region (e.g., the central region 512₁) and the fifth region (e.g., trap region 506₃) of the first set of electrodes, the fourth region (e.g., fast trap region 508₄) of the second set of electrodes is disposed between the first region (e.g., central region 512₂) and the fifth region (e.g., trap region 506₄) of the second set of electrodes. In certain aspects, the width of the first region may be greater than a width of the fourth region and less than a width of the fifth region.

In certain aspects, a dielectric region (e.g., dielectric material 420) disposed between the first set of electrodes and the second set of electrodes. In certain aspects, the first set of electrodes and the second set of electrodes may be configured such that a velocity of an acoustic wave configured to flow between the second region (e.g., the fast trap region 508₃) of one of the first set of electrodes and the second region (e.g., the fast trap region 508₄) of one of the second set of electrodes is greater than a velocity of another acoustic wave configured to flow between the third region (e.g., the trap region 506₃) of one of the first set of electrodes and the third region (e.g., the trap region 506₄) of one of the second set of electrodes

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with discrete hardware components designed to perform the functions described herein.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A surface acoustic wave (SAW) device comprising:
a substrate; and
an interdigitated transducer (IDT) disposed above the substrate and comprising a plurality of electrodes, wherein:
a first electrode of the plurality of electrodes comprises a first region, a second region, and a third region;
the second region is disposed between the first and third regions; and
a width of the first electrode in the first region is greater than a width of the first electrode in the second region and less than a width of the first electrode in the third region.

2. The SAW device of claim 1, wherein:
a second electrode of the plurality of electrodes comprises a fourth region, a fifth region, and a sixth region;
the fifth region is disposed between the fourth and sixth regions; and
a width of the second electrode in the fourth region is greater than a width of the second electrode in the fifth region and less than a width of the second electrode in the sixth region.

3. The SAW device of claim 2, further comprising:
a third electrode of the plurality of electrodes having a seventh region, an eighth region, and a ninth region, wherein:
the third electrode and the second electrode are coupled to a first terminal of the IDT;
the first electrode is coupled to a second terminal of the IDT;
at least a portion of the first electrode is disposed between the second electrode and the third electrode;
the eighth region is disposed between the seventh region and the ninth region; and
a width of the third electrode in the seventh region is greater than a width of the third electrode in the eighth region and less than a width of the second electrode in the ninth region.

4. The SAW device of claim 2, wherein:
the first region of the first electrode is disposed adjacent to the fourth region of the second electrode;
the second region of the first electrode is disposed adjacent to the fifth region of the second electrode; and
the third region of the first electrode is disposed adjacent to the sixth region of the second electrode.

5. The SAW device of claim 4, wherein the first and second electrodes are configured such that a velocity of an acoustic wave configured to flow between the second region and the fifth region is greater than a velocity of another acoustic wave configured to flow between the third region and the sixth region.

6. The SAW device of claim 4, wherein:
the first region of the first electrode and the fourth region of the second electrode have the same length, width, and height;
the second region of the first electrode and the fifth region of the second electrode have the same length, width, and height; and
the third region of the first electrode and the sixth region of the second electrode have the same length, width, and height.

7. The SAW device of claim 2, wherein:
the second electrode comprises a seventh region disposed adjacent to the sixth region of the second electrode; and
a width of the second electrode in the seventh region is greater than the width of the second electrode in the fifth region and less than the width of the second electrode in the sixth region.

8. The SAW device of claim 7, wherein the width of the second electrode in the seventh region is the same as the width of the second electrode in the fourth region.

9. The SAW device of claim 2, wherein:
the first electrode comprises a seventh region and an eighth region;
the seventh region is disposed between the first region and the eighth region; and
the width of the first electrode in the first region is greater than a width of the first electrode in the seventh region and less than a width of the first electrode in the eighth region.

10. The SAW device of claim 9, wherein:
the second electrode comprises a ninth region and a tenth region;
the ninth region is disposed between the fourth region and the tenth region; and
the width of the second electrode in the fourth region is greater than a width of the second electrode in the ninth region and less than a width of the second electrode in the tenth region.

11. The SAW device of claim 10, wherein:
the seventh region of the first electrode is disposed adjacent to the ninth region of the second electrode; and
the eighth region of the first electrode is disposed adjacent to the tenth region of the second electrode.

12. The SAW device of claim 1, wherein a length of the second region is less than a length of the third region in the first electrode.

13. The SAW device of claim 1, further comprising a dielectric region disposed between the plurality of electrodes.

14. The SAW device of claim 1, wherein:
the first electrode further comprises a fourth region and a fifth region;
the fourth region is disposed between the first region and the fifth region; and
the width of the first electrode in the first region is greater than a width of the first electrode in the fourth region and less than a width of the first electrode in the fifth region.

15. The SAW device of claim 14, wherein:
the second and fourth regions of the first electrode have the same width; and
the third and fifth regions of the first electrode have the same width.

16. The SAW device of claim 14, wherein the first, second, third, fourth, and fifth regions of the first electrode are disposed linearly along the same axis, are disposed in the same layer of the SAW device, and have the same height.

17. The SAW device of claim 1, wherein the substrate comprises a piezoelectric substrate.

18. A surface acoustic wave (SAW) device comprising:
a substrate; and
an interdigitated transducer (IDT) disposed above the substrate and comprising a first set of electrodes and a second set of electrodes, wherein:
at least a portion of each of the first set of electrodes is disposed between an adjacent pair of electrodes in the second set of electrodes;
each electrode of the first set of electrodes and the second set of electrodes comprises a first region, a second region, and a third region;
the second region is disposed between the first region and the third region; and
a width of the first region is greater than a width of the second region and less than a width of the third region.

19. The SAW device of claim 18, wherein the first, second, and third regions of one of the first set of electrodes are disposed adjacent to the first, second, and third regions of one of the second set of electrodes, respectively.

20. The SAW device of claim 18, wherein:
each of the first set of electrodes further comprises a fourth region, the fourth region extending beyond a length of each of the second set of electrodes; and
a width of the fourth region is greater than the width of the second region and less than the width of the third region.

21. The SAW device of claim 18, wherein:
the first regions of the first set of electrodes and the second set of electrodes have the same length, width, and height;
the second regions of the first set of electrodes and the second set of electrodes have the same length, width, and height; and
the third regions of the first set of electrodes and the second set of electrodes have the same length, width, and height.

22. The SAW device of claim 18, wherein:
each electrode of the first set of electrodes and the second set of electrodes comprises a fourth region and a fifth region;
the fourth region of the first set of electrodes is disposed between the first region and the fifth region of the first set of electrodes;
the fourth region of the second set of electrodes is disposed between the first region and the fifth region of the second set of electrodes; and
the width of the first region is greater than a width of the fourth region and less than a width of the fifth region.

23. The SAW device of claim 18, wherein the substrate comprises a piezoelectric substrate.

24. The SAW device of claim 18, further comprising a dielectric region disposed between the first set of electrodes and the second set of electrodes.

25. The SAW device of claim 18, wherein the first set of electrodes and the second set of electrodes are configured such that a velocity of an acoustic wave configured to flow between the second region of one of the first set of electrodes and the second region of one of the second set of electrodes is greater than a velocity of another acoustic wave configured to flow between the third region of one of the first set of electrodes and the third region of one of the second set of electrodes.
